(19) United States
(12) Patent Application Publication
(10) Pub. No.: US 2023/0136674 A1
(43) Pub. Date: May 4, 2023

(54) SELF-ALIGNED DOUBLE PATTERNING (SADP) INTEGRATION WITH WIDE LINE SPACING

(71) Applicant: International Business Machines Corporation, Armonk, NY (US)

(72) Inventors: Shyng-Tsong Chen, Rensselaer, NY (US); Terry A. Spooner, Mechanicville, NY (US); Koichi Motoyama, Clifton Park, NY (US); Chih-Chao Yang, Glenmont, NY (US)

(21) Appl. No.: 17/512,720

(22) Filed: Oct. 28, 2021

(51) Int. Cl. H01L 21/033; H01L 21/768; H01L 23/522

(52) U.S. Cl. CPC H01L 21/0338; H01L 21/0335; H01L 21/0337; H01L 21/76802; H01L 21/7684; H01L 21/76877; H01L 23/5226

(57) ABSTRACT

Embodiments of the invention include a method for fabricating a semiconductor device and the resulting structure. Mandrels are patterned on a hardmask, where the hardmask is located on an interlayer dielectric layer. Spacers are formed on sidewalls of the mandrels. The mandrels are removed. A wide spacing masking layer is patterned on the interlayer dielectric layer. Exposed portions of the hardmask are etched such that top surfaces of the ILD layer are exposed. Exposed portions of the ILD layer are etched such that a plurality of trenches are formed within the ILD layer. The plurality of trenches are filled with conductive metal.

### BACKGROUND

The present invention relates generally to the field of semiconductor structures and fabrication, and more particularly to forming patterned features on a substrate by adding a wide line masking scheme to a self-aligned double patterning (SADP) scheme.

Back end of line (BEOL) is the portion of integrated circuit fabrication where the individual devices (transistors, capacitors, resisters, etc.) get interconnected with wiring on the wafer, the metallization layer. BEOL generally begins when the first layer of metal is deposited on the wafer. BEOL includes contacts, insulating layers (dielectrics), metal levels, and bonding sites for chip-to-package connections.

SADP is a form of double patterning sometimes referred to as pitch division, spacer, or sidewall-assisted double patterning. SADP processes typically use a lithography step and additional deposition and etch steps to define a spacer-like feature. In typical SADP processes mandrels are formed on a substrate. The formed pattern of mandrels is then covered with a deposition layer. The deposition layer is etched, forming spacers, and the top portion undergoes chemical mechanical planarization (CMP).

### SUMMARY

Embodiments of the invention include a method for fabricating a semiconductor device and the resulting structure. The method can include patterning mandrels on a hardmask, where the hardmask is located on an interlayer dielectric (ILD) layer. The method can also include forming spacers on sidewalls of the mandrels. The method can also include removing the mandrels. The method can also include patterning a wide spacing masking layer on the ILD layer. The method can also include etching exposed portions of the hardmask such that top surfaces of the ILD layer are exposed. The method can also include etching exposed portions of the ILD layer such that a plurality of trenches are formed within the ILD layer. The method can also include filling the plurality of trenches with conductive metal.

### BRIEF DESCRIPTION OF THE DRAWINGS

FIG. 1 depicts a process of patterning mandrels on a hardmask, the hardmask on an interlayer dielectric (ILD) layer, in accordance with an embodiment of the invention.

FIG. 2 depicts a process of forming a spacer material layer, in accordance with an embodiment of the invention.

FIG. 3 depicts a process of etching top surfaces of the spacer material to expose top surfaces of the mandrels and form spacers, in accordance with an embodiment of the invention.

FIG. 4 depicts a process of removing the mandrels, in accordance with an embodiment of the invention.

FIG. 5 depicts a process of forming a wide spacing masking layer, in accordance with an embodiment of the invention.

FIG. 6 depicts a process of removing portions of the hardmask layer not protected by the spacers or the wide spacing masking layer, in accordance with an embodiment of the invention.

FIG. 7 depicts a process of forming trenches within the ILD layer, in accordance with an embodiment of the invention.

FIG. 8 depicts a process of removing the hardmask, in accordance with an embodiment of the invention.

FIG. 9 depicts a process of forming a metal layer within and above the trenches, in accordance with an embodiment of the invention.

FIG. 10 depicts a process of removing upper portions of the metal layer to expose upper surfaces of the ILD layer, in accordance with an embodiment of the invention.

### DETAILED DESCRIPTION

Embodiments of the present invention recognize that current self-aligned double patterning (SADP) integration only allows one line spacing value, the line spacing value determined by the spacer material thickness. Embodiments of the present invention further recognize that wide lines with small spacing may have shorting and reliability issues. Embodiments of the present invention recognize that utilizing current techniques, the maximum width of a wide line is usually limited to five times the width of the minimum width line, which may not be wide enough for some chip applications that require a wider line (e.g., to carry more current). Embodiments of the present invention recognize that existing SADP processes use larger spacing blocks with edges landing above spacers in order to create larger spacing between lines. However, such an approach usually results in patterning defects as it is difficult to optimize the large block shapes such that all edges land exactly above the center of spacers. In addition, alignment error and process variations may cause pattern defects.

Embodiments of the present invention disclose a fabrication method and structure that adds a wide line masking scheme to an SADP scheme in order to make it possible to have wider lines with line spacing larger than the minimum spacing. Wide line masks are within the spacing between spacers, eliminating possible pattern defects that may occur when using conventional approaches.

It is understood in advance that although example embodiments of the invention are described in connection with a particular transistor architecture, embodiments of the invention are not limited to the particular transistor architectures or materials described in this specification. Rather, embodiments of the present invention are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “an example embodiment,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “overlaying,” “atop,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Turning now to an overview of technologies that are more specifically relevant to aspects of the present invention, ICs are fabricated in a series of stages, including a front-end-of-line (FEOL) stage, a middle-of-line (MOL) stage, and a BEOL stage. The process flows for fabricating modern ICs are often identified based on whether the process flows fall in the FEOL stage, the MOL stage, or the BEOL stage. Generally, the FEOL stage is where device elements (e.g., transistors, capacitors, resistors) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another.

Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

One of the most common uses of a SADP process is to form high density arrays of parallel lines. A positive tone SADP process uses the spacers as the etch mask, resulting in lines of the same width. While this lends itself readily to forming bit lines, wider lines and features (e.g., pads, power supply lines, string select lines) are usually necessary on the same layer to form working devices. A negative tone SADP process introduces a gapfill material between the spacers. The gapfill material is then planarized, the spacers are removed and the gapfill material serves as the etch mask. Thus, in a negative tone SADP process the trenches are the same width and the widths of the line may be varied within an integrated circuit. Removing the constraint of having constant line widths or constant trench widths enables circuit designers to use SADP with more flexibility.

The present invention will now be described in detail with reference to the Figures.

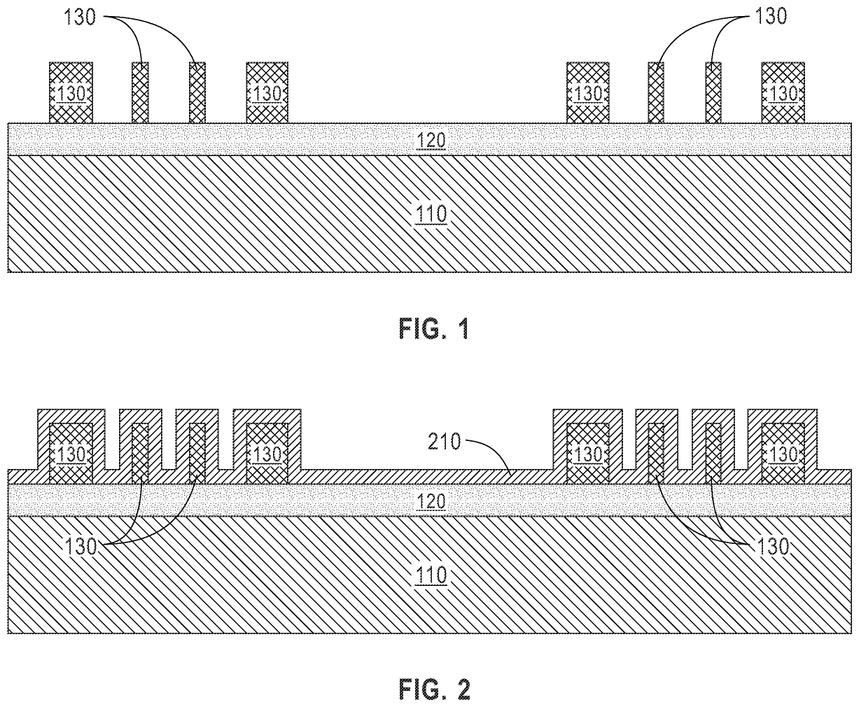

FIG. 1 depicts a cross-sectional view of a device at an early stage in the method of forming the device and after an initial set of fabrication operations according to one embodiment of the invention. FIG. 1 shows the formation of a pattern of mandrels.

The semiconductor structure of FIG. 1 includes hardmask 120 formed above interlayer dielectric (ILD) 110. Mandrels 130 are formed and patterned above hardmask 120.

ILD 110 can be made of any suitable dielectric material, such as, for example, low-κ dielectrics (i.e., materials having a small dielectric constant relative to silicon dioxide, i.e., less than about 3.9), ultra-low-κ dielectrics (i.e., materials having a dielectric constant less than 3), porous silicates, carbon doped oxides, silicon dioxides, silicon nitrides, silicon oxynitrides, silicon carbide (SiC), or other dielectric materials. Any known manner of forming the dielectric layer 104 can be utilized, such as, for example, chemical vapor deposition (CVD), plasma-enhanced chemical vapor deposition (PECVD), atomic layer deposition (ALD), flowable CVD, spin-on dielectrics, or physical vapor deposition (PVD).

Hardmask 120 is deposited on top of ILD 110. A hardmask is a material used in semiconductor processing as an etch mask. Hardmask 120 is composed of metal or a dielectric material such as, for example, such as, for example, a low-κ dielectric, a nitride, silicon nitride, silicon oxide, SiON, SiC, SiOCN, or SiBCN. In some embodiments of the invention, hardmask 120 is a silicon nitride or silicon oxide hardmask. In some embodiments of the invention, hardmask 120 is formed to a thickness of about 5 nm to about 60 nm, for example 30 nm, although other thicknesses are within the contemplated scope of the invention. Hardmask 120 may be deposited using, for example, any suitable process, such as CVD, PECVD, ultrahigh vacuum chemical vapor deposition (UHVCVD), rapid thermal chemical vapor deposition (RTCVD), metalorganic chemical vapor deposition (MOCVD), low-pressure chemical vapor deposition (LPCVD), limited reaction processing CVD (LRPCVD), atomic layer deposition (ALD), flowable CVD, spin-on dielectrics, PVD, molecular beam epitaxy (MBE), chemical solution deposition, spin-on dielectrics, or other like process.

Mandrels 130 are initially formed as a layer of mandrel material above hardmask 120. Mandrels 130 are used in spacer patterning. Spacer patterning is a technique employed for patterning features with linewidths smaller than can be achieved by conventional lithography. While not depicted, a patterned layer of photoresist, typically referred to as a “mandrel mask” may be formed above the layer of mandrel material using, for example, single exposure photolithography tools and techniques. A photoresist is a light-sensitive material used in processes, such as photolithography, to form a patterned coating on a surface. The photoresist may be a light-sensitive polymer. In various embodiments, standard photolithographic processes are used to define a pattern of mandrels 130 in a layer of photoresist deposited on mandrels 130. The desired mandrel 130 pattern may then be formed in the layer of mandrel material by removing the layer of mandrel material from the areas not protected by the pattern in the photoresist layer. Such portions of the layer of mandrel material are removed using, for example, reactive ion etching (RIE). RIE uses chemically reactive plasma, generated by an electromagnetic field, to remove various materials. A person of ordinary skill in the art will recognize that the type of plasma used will depend on the material of which mandrels 130 are composed, or that other etch processes such as wet chemical etching or laser ablation may be used. Mandrels 130 may be comprised of a material that may be selectively etched with respect to hardmask 120 and may be, for example, a metal or dielectric material, such as the materials discussed with respect to hardmask 120, so long as mandrels 130 may be selectively etched with respect to hardmask 120.

As depicted in FIG. 1, mandrels 130 are patterned such that some of the mandrel lines are wider than other mandrel lines. In the depicted embodiment, the wider mandrel 130 lines are three times wider than the thinner mandrel 130 lines. Embodiments of the present invention contemplate a variety of thicknesses and patterns based on the desired requirements of the resulting structure and present the embodiment depicted by FIGS. 1-10 merely as one example.

FIG. 2 depicts a cross-sectional view of fabrication steps, in accordance with an embodiment of the present invention. FIG. 2 shows the formation of spacer 210.

A layer of spacer 210 material is deposited on exposed surfaces of hardmask 120 and on and around exposed surfaces of mandrels 130. Spacer 210 material may be deposited by performing a conformal deposition process. Spacer 210 material is of a material that may be selectively etched relative to hardmask 120 and mandrels 130 and may be, for example, a metal or dielectric material, such as the materials discussed with respect to hardmask 120, so long as spacer 210 may be selectively etched with respect to hardmask 120 and mandrels 130.

As depicted in FIG. 1, the lateral thickness of spacer 210 material is equal to the thickness of the thinner mandrel 130 lines.

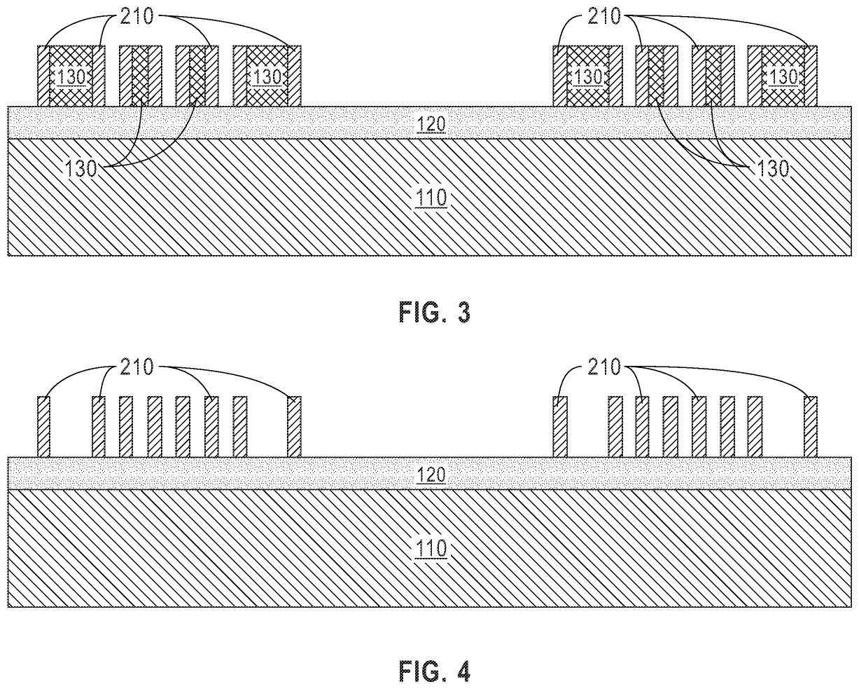

FIG. 3 depicts a cross-sectional view of fabrication steps, in accordance with an embodiment of the present invention. FIG. 3 shows the etch back of spacer 210 to expose top surfaces of mandrels 130.

An anisotropic etching process may be performed on the upper portion of spacer 210 material to define a plurality of spacers 210. In the depicted embodiment, each of the spacers 210 has a lateral width equal to the thinner mandrels 130 and are located on the sidewalls of each mandrel 130. The width of spacers 210 may vary based on the particular device under construction.

FIG. 4 depicts a cross-sectional view of fabrication steps, in accordance with an embodiment of the present invention. FIG. 4 shows the removal of mandrels 130.

An etching process that is selective in removing physically exposed portions of mandrels 130 relative to hardmask 120 and spacers 210 is used to remove mandrels 130. The etching process utilized may be a dry etching or wet etching process.

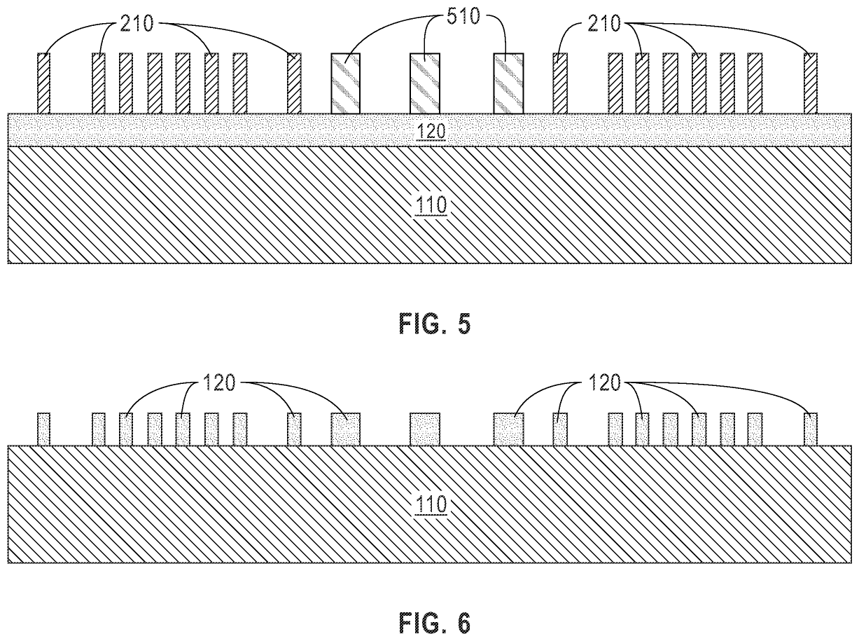

FIG. 5 depicts a cross-sectional view of fabrication steps, in accordance with an embodiment of the present invention. FIG. 5 shows the formation of wide spacing masking layer 510.

Wide spacing masking layer 510 may be deposited on top of hardmask 120 and/or spacers 210. Wide spacing masking layer 510 may be, for example, a metal or dielectric material, such as the materials discussed with respect to hardmask 120, so long as wide spacing masking layer 510 may be selectively etched with respect to hardmask 120 and spacers 210. In various embodiments, standard photolithographic processes are used to define a pattern of wide spacing masking layer 510 in a layer of photoresist (not shown) deposited on wide spacing masking layer 510. The desired wide spacing masking layer pattern may then be formed in wide spacing masking layer 510 by removing wide spacing masking layer 510 from the areas not protected by the pattern in the photoresist. An etching process, such as RIE, laser ablation, or any etch process which can be used to selectively remove wide spacing masking layer 510 not protected by the layer of photoresist may be used.

FIG. 6 depicts a cross-sectional view of fabrication steps in accordance with an embodiment of the present invention. FIG. 6 shows the removal of hardmask 120 not protected by spacers 210 or wide spacing masking layer 510 and the subsequent removal of spacers 210 and wide spacing masking layer 510.

An etching process, such as RIE, laser ablation, or any etch process which can be used to selectively remove a portion of material such as hardmask 120, may be utilized. The etching process only removes the portions of hardmask 120 not protected by spacers 210 or wide spacing masking layer 510. Portions of hardmask 120 are etched such that top surfaces of ILD 110 are exposed.

Subsequent to removing the portions of hardmask 120 to expose top surfaces of ILD 110, spacers 210 and wide spacing masking layer 510 is removed.

In general, the process of removing spacers 210 and wide spacing masking layer 510 involves the use of one or more etching processes, such as RIE, laser ablation, or any etch process which can be used to selectively remove a portion of material, such as spacers 210 and/or wide spacing masking layer 510.

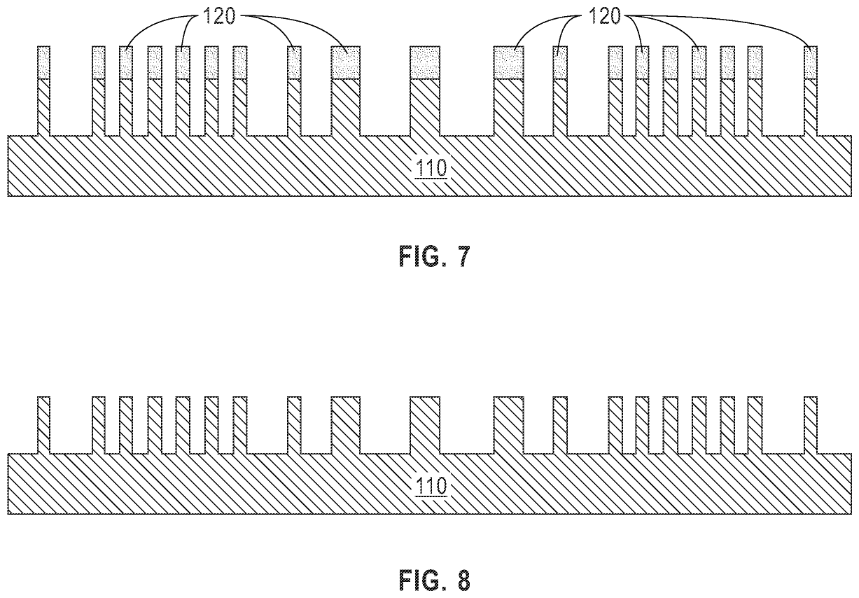

FIG. 7 depicts a cross-sectional view of fabrication steps in accordance with an embodiment of the present invention. FIG. 7 shows the formation of trenches within ILD 110.

An etching process is performed on ILD 110 through the patterned hardmask 120 to define trenches in the layer of ILD 110. The etching process may be, for example, RIE, laser ablation, or any etch process which can be used to selectively remove a portion of material such as ILD 110. The etching process only removes the portions of ILD 110 not protected by hardmask 120. The etching process is performed such that the trenches are of a depth desired for a metal line or other possible feature of the resulting structure.

FIG. 8 depicts a cross-sectional view of fabrication steps in accordance with an embodiment of the present invention. FIG. 8 shows the removal of hardmask 120.

In general, the process of removing hardmask 120 involves the use of an etching process such as RIE, laser ablation, or any etch process which can be used to selectively remove a portion of material, such as hardmask 120.

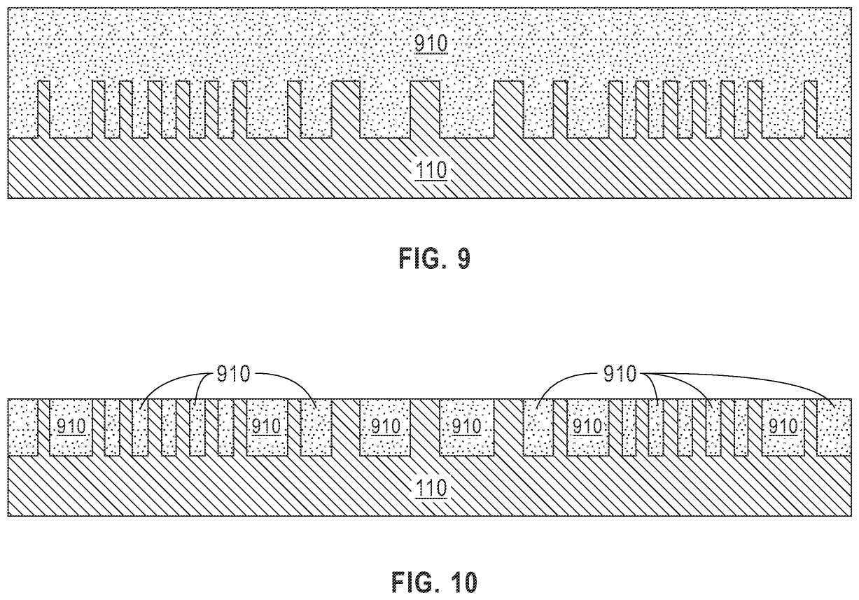

FIG. 9 depicts a cross-sectional view of fabrication steps in accordance with an embodiment of the present invention. FIG. 9 shows the formation of metal layer 910 within and above the trenches.

Metal layer 910 may be any type of conductive metal. For example, metal layer 610 may be composed of Cu, Ru, Co, Mo, W, Al, or Rh. Metal layer 910 may be deposited using, for example, CVD, PECVD, PVD, or other deposition processes. As depicted in FIG. 9, metal layer 910 is deposited above the desired height.

In some embodiments, a liner (not shown) may be deposited prior to the deposition of metal layer 910 such that, metal layer 910 is deposited on the liner both within and above the trenches.

The liner may be formed on ILD 110 by sputtering, CVD, or ALD and may be a conductor such as titanium nitride (TiN), titanium aluminum carbine (TiAlC), titanium carbine (TiC), or tantalum nitride (TaN). In some embodiments, liner 220 may be comprised of other conductive materials such as aluminum (Al), copper (Cu), nickel (Ni), cobalt (Co), ruthenium (Ru), or combinations thereof.

FIG. 10 depicts a cross-sectional view of fabrication steps in accordance with an embodiment of the present invention. FIG. 10 shows the removal of upper portions of metal layer 910 to expose the upper surfaces of ILD 110.

As described above, with reference to FIG. 9, metal layer 910 may be deposited above the desired height. Subsequently, utilizing a planarization process, such as CMP, the height of metal layer 910 may be reduced such that the upper surfaces of ILD 110 are exposed.

The resulting structure includes lines with both minimum spacing and wider spacing. The wider lines being of a width that is not be possible when using only conventional SADP schemes. For example, the wider lines may be greater than five times the width of the lines with minimum spacing. The larger line spacing can allow a larger current to pass through wide lines with decreased reliability concerns. Further, when forming the structure, as larger spacing blocks do not have to edge land on a spacer pattern, possible defects are eliminated that may result from alignment error and/or process variations. As previously described, the resulting structure depicted in FIG. 10 is but one example, and the particular layout of lines, both with minimum and wider spacing, may vary based on the final structure desired.

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A method comprising:
patterning mandrels on a hardmask, wherein the hardmask is located on an interlayer dielectric (ILD) layer;
forming spacers on sidewalls of the mandrels;
removing the mandrels;
patterning a wide spacing masking layer on the ILD layer;
etching exposed portions of the hardmask such that top surfaces of the ILD layer are exposed;
etching exposed portions of the ILD layer such that a plurality of trenches are formed within the ILD layer; and
filling the plurality of trenches with conductive metal.

2. The method of claim 1, wherein forming the spacers on the sidewalls of the mandrels comprises:
depositing a layer of spacer material on exposed surfaces of the mandrels; and
etching upper portions of the spacer material to expose top surfaces of the mandrels.

3. The method of claim 1, wherein patterning the wide spacing masking layer comprises:
depositing a wide spacing masking material layer on top of the hardmask and the spacers;
defining a pattern of the wide spacing masking material layer in a layer of photoresist deposited on the wide spacing masking material layer; and
selectively etching portions of the wide spacing masking material layer unprotected by the pattern in the photoresist.

4. The method of claim 1, further comprising:
prior to filling the plurality of trenches with the conductive metal, removing remaining portions of the hardmask.

5. The method of claim 1, wherein the plurality of trenches comprise:
a first set of trenches of a first width; and
a second set of trenches of a second width, the second width greater than the first width.

6. The method of claim 1, wherein filling the plurality of trenches with conductive metal comprises:
depositing a conductive metal layer within the trenches and on upper surfaces of the ILD layer above a desired height; and
utilizing a planarization process to reduce a height of the conductive metal layer such that the upper surfaces of the ILD layer are exposed.

7. The method of claim 5, wherein the second width is greater than five times the first width.

8. The method of claim 1, wherein a top surface of the conductive metal is coplanar with a top surface of the ILD layer.

9. The method of claim 1, wherein the conductive metal is a material selected from the group consisting of Cu, Ru, Co, Mo, W, Al, and Rh.

10. The method of claim 1, wherein the ILD layer is a material selected from the group consisting of: low-κ dielectric, ultra-low-κ dielectric, porous silicate, carbon doped oxide, silicon dioxide, silicon nitride, silicon oxynitride, and silicon carbide.

11. The method of claim 1, wherein the wide spacing masking layer is of a material selectively etchable with respect to the hardmask and the spacers, the material selected from the group consisting of: a metal and a dielectric.

12. The method of claim 1, wherein the mandrels are of a material selectively etchable with respect to the hardmask, the material selected form the group consisting of: a metal and a dielectric.

13. The method of claim 1, wherein the mandrels comprise a first mandrel of a first width and a second mandrel of a second width, the second width greater than the first width.

14. The method of claim 13, wherein a width of each of the spacers is equal to the first width.

15. The method of claim 13, wherein the second width is three times the first width

16. A semiconductor structure comprising:
an interlayer dielectric (ILD) layer patterned to have a plurality of trenches, the plurality of trenches comprising:
a first set of trenches of a first width; and
a second set of trenches of a second width, the second width greater than the first width; and
conductive metal lines positioned within the pluralities of trenches.

17. The semiconductor structure of claim 16, wherein a top surface of each of the conductive metal lines is coplanar with a top surface of the ILD layer.

18. The semiconductor structure of claim 16, wherein the second width is greater than five times the first width.

19. The semiconductor structure of claim 16, wherein the conductive metal lines are a material selected from the group consisting of: Cu, Ru, Co, Mo, W, Al, and Rh.

20. The semiconductor structure of claim 16, wherein the ILD layer is a material selected from the group consisting of: low-κ dielectric, ultra-low-κ dielectric, porous silicate, carbon doped oxide, silicon dioxide, silicon nitride, silicon oxynitride, and silicon carbide.
